(19) United States
(12) Patent Application Publication
(10) Pub. No.: US 2023/0133316 A1
(43) Pub. Date: May 4, 2023

(54) LASER

(71) Applicant: ROCKLEY PHOTONICS LIMITED, Altrincham (GB)

(72) Inventor: Xuejin YAN, Santa Clara, CA (US)

(21) Appl. No.: 18/051,848

(22) Filed: Nov. 1, 2022

(30) Foreign Application Priority Data
Nov. 2, 2021 (GB) 2115742.5

(51) Int. Cl. H01S 5/125; H01S 5/02; H01S 5/026; H01S 5/024; H01S 5/14

(52) U.S. Cl. CPC H01S 5/125; H01S 5/021; H01S 5/026; H01S 5/02453; H01S 5/141

(57) ABSTRACT

A laser comprising a photonic component comprising a gain medium; and a waveguide platform comprising a Distributed Bragg Reflector, DBR, section. The photonic component is optically coupled to the waveguide platform. One or more thermal heaters are positioned at the DBR section of the waveguide platform, and/or at a phase section of the waveguide platform located between the gain medium and the DBR section.

### CROSS-REFERENCE TO RELATED APPLICATION(S)

This application claims priority to United Kingdom Patent Application No. 2115742.5, filed in the United Kingdom Intellectual Property Office on Nov. 2, 2021, entitled “LASER”, which is incorporated by reference herein in its entirety.

### FIELD

One or more aspects of embodiments according to the present invention relate to a laser and methods for characterizing a laser, and more particularly, although not exclusively, to a laser comprising a Distributed Bragg Reflector, DBR, section and a phase tuning section.

### BACKGROUND

Distributed Bragg Reflector (DBR) lasers generally include three sections: a gain region, in which a single spatial lasing mode is generated, a phase region, and a distributed Bragg grating (DBR) region. The gain regions includes a light source, and operates to generate and amplify light. The DBR region comprises an optical mirror whose reflection is wavelength selective and only offers strong reflection within a narrow wavelength range depending on the laser longitudinal mode space. For a DBR laser there are generally a plurality of longitudinal modes, but the DBR mirror only offers significant reflection to a single mode, wherein other modes of light undergo much greater loss compared to the lasing mode.

A DBR laser is also wavelength-tunable. It is known to alter the wavelength of light output by the laser by injecting current into the DBR section.

In an ideal laser, the main spectral peak contains all the power produced by the laser, such that the laser is operating at a single mode (i.e. a single wavelength). External cavity DBR lasers are usually a type of single mode optical source. However, in reality, if the loss between two modes in the cavity is not large enough, the laser signal may contain side peaks, or “side modes”, also containing significant energy in the cavity.

Side mode suppress ratio (SMSR) is used to define whether a DBR laser works at a single mode, or at multi-mode. Generally, if the SMSR is larger than 40 dB, the DBR laser is working at a single mode with most power existing in the main mode, as preferred. Otherwise, if the SMSR is less than 40 dB, the DBR laser is working at multi-mode. There is a need to improve the optical source yield of DBR lasers, including improving the SMSR of DBR lasers.

### SUMMARY

Accordingly, the present invention aims to solve the above problems by providing, according to a first aspect, a laser comprising:

a photonic component comprising a gain medium; and

a waveguide platform comprising a Distributed Bragg Reflector, DBR, section, wherein the photonic component is optically coupled to the waveguide platform, and wherein one or more thermal heaters are positioned at the DBR section of the waveguide platform, and/or at a phase section of the waveguide platform located between the gain medium and the DBR section.

By providing one or more thermal heaters at the DBR section and/or at a phase section of the waveguide platform, the respective section of the waveguide can be heated. When a thermal heater is provided at the DBR section, this results in the DBR grating reflection spectrum peak shifting to a longer wavelength position with increasing temperature, and its reflection spectral profile remains unchanged. When a thermal heater is provided at the phase section, the thermal heater can be used for DBR laser phase tuning for the best SMSR. The result of this wavelength and/or phase tuning, is that the SMSR of the laser may be improved, thus resulting in an improvement in laser source yield.

Optional features of the invention will now be set out. These are applicable singly or in any combination with any aspect of the present disclosure.

The waveguide platform may be a silicon on insulator, SOI, or a silicon nitride platform.

The photonic component may be a III-V semiconductor based photonic component, that is the photonic component may be made of III-V materials. The photonic component may comprise a Reflection Semiconductor Optical Amplifier, RSOA. The photonic component may be configured to function as a gain chip for the laser. The photonic component may include a waveguide, such as a mode size converter.

The DBR section may comprise an optical mirror configured to selectively reflect light having a wavelength within a predetermined range of wavelengths. As such, the optical mirror may only offer a strong reflection within a narrow wavelength range, wherein other modes of light undergo greater loss compared to light within the narrow wavelength range.

The waveguide platform may comprise a phase section located between the gain medium and the DBR section. The phase section of the waveguide platform may be thermally isolated from the DBR section. For example, the phase section may be thermally isolated from the DBR section by a thermal isolation space between the phase section and the DBR section.

The phase section of the waveguide platform may be optically coupled to the photonic component, and in particular a waveguide of the photonic component, e.g. by a silicon edge coupler. The silicon edge coupler may overlap a waveguide of the photonic component.

The one or more heaters may comprise metal, for example TiN. The one or more heaters may comprise heavy doped silicon.

A first heater may be positioned on the phase section of the waveguide platform and a second heater may be position on the DBR section of the waveguide platform. Alternatively, only the DBR section may have a heater positioned thereon, or the phase section have a heater positioned thereon.

The one or more heaters may be configured to receive power from one or more power sources. The photonic component may be configured to receive power from one or more power sources, which may be the same or different power sources to the one or more power sources which provide power to the one or more heaters.

The waveguide platform may comprise a ridge waveguide or a rib waveguide. The waveguide platform may comprise a ridge. One or more heaters may be positioned on the ridge of the waveguide platform. Alternatively/additionally, one or more heaters may be positioned adjacent to the ridge of the waveguide platform, and may extend in a longitudinal direction parallel to the ridge of the waveguide platform. Temperature sensors may be positioned near or adjacent to the phase section and DBR section to detect the temperature of the phase section and DBR section.

The one or more heaters may be spaced from the DBR section/phase section by an oxide layer. In particular, an oxide layer may be positioned between the heater(s) and the DBR section and/or phase section. The oxide layer may be a silicon dioxide, SiO₂, layer. The oxide layer between the heater(s) and the DBR section and/or phase section may have a thickness of between 50 nm and 500 nm.

Thermal tuning of the laser allows for self-characterization, self-calibration and self-optimization of the laser operating points, such as operating wavelength and SMSR values, automatically.

In particular, according to a second aspect, there is provided a method of characterizing a laser according to the first aspect, wherein the laser comprises a DBR heater positioned at the DBR section, the method comprising:

determining an optimal DBR heater power value to be supplied to the DBR heater, wherein determining the optimal DBR heater power value comprises:
providing power to the photonic component;
providing power to the phase heater;
monitoring the output power of the laser as power provided to the DBR heater is increased; and
selecting the optimal DBR heater power value based on the monitored output power of the laser.

In this way, the laser can perform self-characterization by itself, without human intervention. In particular, the laser output power can be optimized by determining an optimal value for the power supplied to the DBR heater. Accordingly, as the laser can self-characterize, the characterization can be performed in a much more time efficient manner, compared to previous methods where the optimal setting points are required to be found by manual testing. This may be more labour and time cost efficient, especially during large scale production of the lasers. Furthermore, the laser may be able to repeatedly self-characterize. This may be advantageous due to element ageing issues as a result of, for example, laser wavelength drift over time (e.g. so that the laser can self-recalibrate and reset its gain bias current, DBR heater power value and optionally phase heater power value, to compensate for laser wavelength drift), or due to environmental changes (e.g. seasonal changes in temperature). Ageing issues may also affect the coupling efficiency of the photonic component with the waveguide platform. In particular, the relative position of the photonic component and the waveguide platform may shift over time as the laser is used, changing the laser threshold current value. The gain of the photonic component (e.g. RSOA), and the DBR section reflection peak, may also change over time. Each of these changes can alter the performance of the laser, but these changes can be compensated for by performing the self-characterization method as disclosed herein. The self-characterization method may be performed upon detection that the laser performance is shifting from an optical working point or is degrading.

The power provided to the DBR heater may be increased in a step-wise manner (i.e. at a constant, discrete step value).

The selected optimal DBR heater power value may correspond to a local maximum of the monitored output power of the laser as the power supplied to the DBR heater is increased. By selecting the optimal DBR heater power value to correspond to a local maximum of the monitored output power of the laser, the performance (e.g. output power) of the laser can be maximised.

Generally, selecting local extremes (i.e. local maximum/minimum values) of the laser output power for laser self-characterization is advantageous as local extremes are computationally simpler to find compared to other approaches.

Optionally, the method may further comprise sampling and averaging a subset of the monitored values of the output power of the laser as power provided to the DBR heater is increased in order to remove noise.

The power provided to the photonic component may be a predefined value, e.g. set by an application of the laser.

The method may also comprise monitoring wavelength of the laser as power provided to the DBR heater is increased.

The monitored values of the output power of the laser and the corresponding values of DBR heater power may be recorded in a memory storage.

Preferably, the laser comprises a phase heater positioned at the phase section. Then, the method may comprise:

determining an optimal phase heater power value to be supplied to the phase heater, wherein determining the optimal phase heater power comprises:
providing power to the photonic component;
providing power to the DBR value at the selected optimal DBR heater power value;
monitoring the output power of the laser as power provided to the phase heater is increased; and
selecting the optimal phase heater power value based on the monitored output power value of the laser.

In this way the SMSR of the laser can be optimized by determining an optimal value for the power supplied to the phase heater.

The power provided to the phase heater may be increased in a step-wise manner (i.e. at a constant, discrete step value).

The selected optimal phase heater power value may correspond to a local minimum of the monitored output power of the laser as the power supplied to the phase heater is increased. Advantageously, the SMSR is optimized (i.e. maximized) at the minimum values (i.e. at the local minimum values) of the laser output power. The lowest power value of the phase heater values may be chosen as the optimal phaser heater power value.

A phase heater power value corresponding to a minimum value of laser output power may be calculated by dividing the sum of the phase heater power values corresponding to two adjacent maximum values of laser output power, by 2.

Optionally, the method may further comprise sampling and averaging a subset of the monitored values of the output power of the laser as power provided to the phase heater is increased in order to remove noise.

The method may also comprise monitoring the wavelength of the laser as power provided to the phase heater is increased.

The monitored values of the output power of the laser and the corresponding values of phase heater power may be recorded in a memory storage.

The method may further comprise operating the laser. The laser may be operated using the determined optimal DBR heater power value and the determined optimal phase heater power value.

The method may be a computer-implemented method.

The method of the second aspect may include any combination of some, all, or none of the above described preferred and optional features.

According to a third aspect, there is provided a system for characterizing a laser, wherein the system is configured to perform the method of the second aspect. The system may comprise a controller, wherein the controller is configured to perform the method of the second aspect. The output power of the laser may be monitored by a monitor photodiode detector (MPD), for example.

According to a fourth aspect, there is provided a spectrometer comprising:

a plurality of lasers according to the first aspect;

an optical manipulation region comprising an optical multiplexer, the optical manipulation region being optically coupled to each of the plurality of devices; and

an optical output for light originating from the plurality of lasers.

According to a fifth aspect, there is provided a method of characterizing a spectrometer according to the fourth aspect, wherein each laser in the spectrometer comprises a DBR heater positioned at the DBR section, the method comprising:

determining an optimal DBR heater power value to be supplied to the DBR heater of a first laser of the plurality of lasers, wherein determining the optimal DBR heater power value for the first laser comprises:

(i) providing power to the photonic component of the first laser;

(ii) monitoring the output power of the optical multiplexer as power provided to the DBR heater of the first laser is increased;

(iii) selecting the optimal DBR heater power value of the first laser, wherein the selected optimal DBR heater power value corresponds to a maximum output power of the optical multiplexer as the power supplied to the DBR heater of the first laser is increased; and

determining an optimal DBR heater power value to be supplied to the DBR heater of each of the remaining lasers of the plurality of lasers by performing steps (i)-(iii) for each of the remaining lasers in turn.

By selecting each optimal DBR heater power value to correspond to a maximum output power of the optical multiplexer, it can be ensured that the output power of the multiplexer is optimized (i.e. maximized).

The power supplied to the DBR heater may be increased in a step-wise manner (i.e. at a constant, discrete step value).

The method may further comprise monitoring the output wavelength of the spectrometer.

It is to be understood that characterizing the spectrometer may include aligning the output wavelength of each laser source with the optical multiplexer pass band peak.

The method of the fifth aspect may be performed after the method of the second aspect, for example. As such, an optimal DBR heater power value for each laser, when the lasers are coupled to the optical multiplexer, may be determined. The optimal phase heater power value for each laser, when the lasers are coupled to the optical multiplexer, may correspond to the respective determined optimal phase heater power values as determined for each laser individually in the method of the second aspect. In some embodiments, only the DBR heater power preferred values which are related to local extreme laser output power may be selected. This can help reduce power consumption of the tuning process.

The method may further comprise operating the spectrometer. The spectrometer may be operated using the determined optimal DBR heater power values and the determined optimal phase heater power values for each laser of the plurality of lasers.

The method may be a computer-implemented method.

According to a sixth aspect, there is provided a system for characterizing a spectrometer, wherein the system is configured to perform the method of the fifth aspect. The system may comprise a controller, wherein the controller is configured to perform the method of the fifth aspect. The output power of the optical multiplexer may be monitored by a monitor photodiode detector (MPD), for example.

The invention includes the combination of the aspects and preferred features described except where such a combination is clearly impermissible or expressly avoided.

### BRIEF DESCRIPTION OF THE DRAWINGS

Embodiments of the invention will now be described by way of example with reference to the accompanying drawings in which:

FIG. 1 is a schematic of a laser according to an embodiment of the present invention;

FIG. 2A shows a perspective view of a laser according to an embodiment of the present invention;

FIG. 2B shows a cross-sectional view of a laser according to an embodiment of the present invention;

FIG. 3 is a perspective view of a laser according to an embodiment of the present invention;

FIG. 4 is a schematic of a laser according to an embodiment of the present invention;

FIG. 5A and FIG. 5B are graphs showing the DBR grating power reflection spectrum of a laser;

FIG. 6 includes graphs showing the effect of increasing the power of a DBR section heater on laser wavelength and laser output power;

FIG. 7 includes graphs showing the effect of increasing the power of a phase section heater on laser wavelength and laser output power;

FIG. 8 is a schematic of a system 60 for self-characterizing a DBR laser;

FIG. 9 is a flow diagram for a laser self-characterization method;

FIG. 10 is a schematic of a system for self-characterizing a spectrometer including a plurality of DBR lasers;

FIG. 11 is a graph of an optical wavelength multiplexer channel pass band profile;

FIG. 12 is a graph of the power spectrum of an optical multiplexer with respect to DBR heater power; and

FIG. 13 is a graph of the power spectrum of an optical multiplexer with respect to selected DBR heater power values.

### DETAILED DESCRIPTION

The detailed description set forth below in connection with the appended drawings is intended as a description of exemplary embodiments of a laser and a method for operating a laser provided in accordance with the present invention and is not intended to represent the only forms in which the present invention may be constructed or utilized.

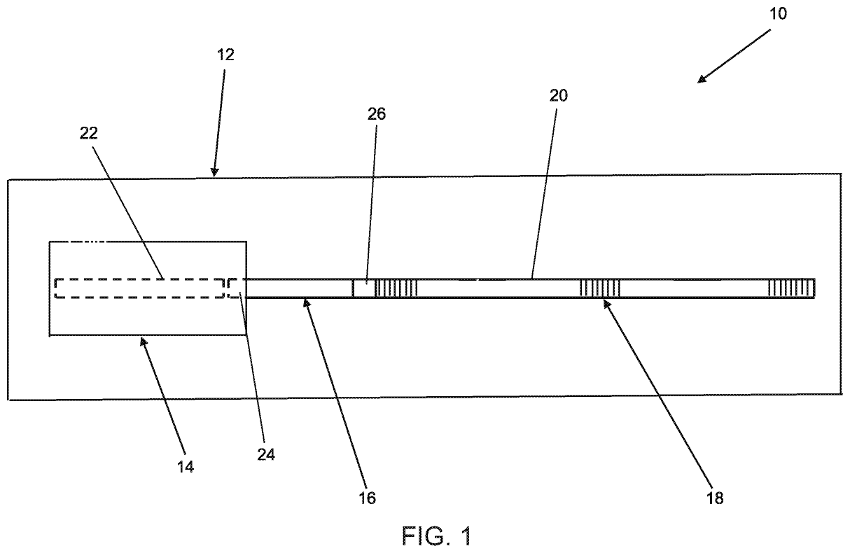

FIG. 1 shows a laser 10 comprising a silicon-on-insulator chip 12, and with three sections; a gain section 14, a phase section 16 and a Distributed Bragg Reflector (DBR) section 18. The phase section 16 is located at a position between the gain section 14 and the DBR section 18. The phase section 16 and DBR section 18 are formed on a silicon waveguide platform 20 having a ridge. In the embodiments shown, the waveguide platform 20 is a rib waveguide. The waveguide platform may be a ridge waveguide. The gain section 14 comprises a gain medium and waveguide ridge 22.

In FIG. 1, gain section 14 is a III-V gain chip within a mounting cavity of the silicon-on-insulator chip 12, wherein the gain chip is flipped on the silicon-on-insulator chip 12. As shown in FIG. 1, an Si edge coupler 24 couples the waveguide ride 22 of the III-V gain chip with the phase section 16 of the silicon waveguide 20 by an overlap between the gain chip 14 and the Si edge coupler 24. The III-V gain chip length (in a direction parallel to the silicon waveguide 20) may be approximately 700 μm and the length (in a direction parallel to the silicon waveguide 20) of the overlap between the gain chip 14 and the Si edge coupler 24 may be approximately 50 μm. The length (in a direction parallel to the silicon waveguide 20) of the phase section 16 of the Si waveguide may be approximately 50 μm, for example. The length (in a direction parallel to the silicon waveguide 20) of the DBR section 18 may be approximately 1000 μm.

The phase section 16 may be thermally isolated from the DBR section 18 of the silicon waveguide 20 by a thermal isolation space 26. The length (in a direction parallel to the silicon waveguide 20) of the thermal isolation space 26 may be approximately 30 μm, for example.

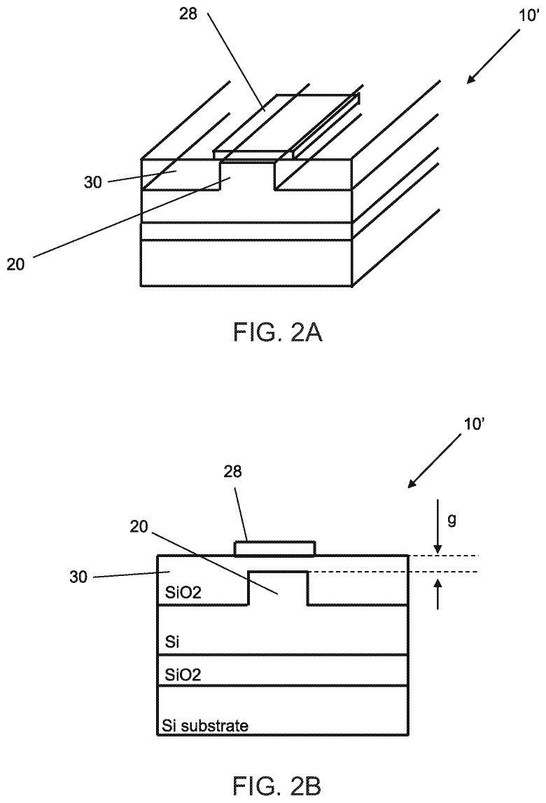

FIG. 2A is a perspective view of laser 10′, which may be an example of laser 10. A heater 28 is positioned above (with respect to a silicon substrate of the silicon-on-insulator chip 12) a ridge of the silicon waveguide 20 at the DBR section 18. For completeness, a heater may also be positioned above the ridge of the silicon waveguide 20 at the phase section 16. As best show in FIG. 2B, which is a cross-sectional view of the laser 10′ shown in FIG. 2A, an oxide layer 30 (in this example, a silicon oxide layer) is positioned between the ridge of the silicon waveguide 20 and the heater 28, such that the heater 28 is spaced from the ridge of the silicon waveguide 20 by a gap g. The heater 28 may comprise metal, such as titanium nitride, TiN, for example. Alternatively, the heater 28 may be a heavy doped (p+ or n+) silicon heater. The thickness of the heater 28 (i.e. in a direction parallel to the thickness of gap g) may be approximately 200 nm, with a width of approximately 3.0 μm, for example. Gap g thickness may be between 50 nm and 500 nm, for example.

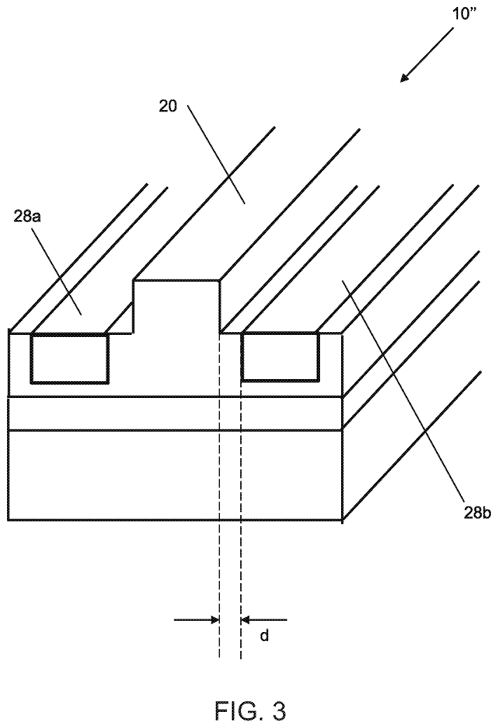

FIG. 3 is a perspective view of laser 10″, which may be an example of laser 10. Laser 10″ is similar to laser 10′, except that there are two heaters 28a, 28b positioned at the DBR section 18 (two heaters may also be positioned at the phase section 16), and the heaters 28a, 28b are not positioned above the ridge of the silicon waveguide 20, but are instead positioned adjacent to the ridge of the silicon waveguide 20. In particular, heaters 28a and 28b are positioned on either side of the ridge of the silicon waveguide 20 (in a slab of the waveguide), spaced from the ridge of the silicon waveguide 20 by a distance d. The heaters 28a, 28b extend longitudinally in a direction parallel to the length of the silicon waveguide 20. The heaters 28a, 28b may comprise metal, such as TiN, for example. Alternatively, the heaters 28a, 28b may be heavy doped p+ or n+ silicon heaters.

When the heater(s) is a heavy doped silicon heater, the heater may have a doping level of 8×10¹⁹ cm⁻³.

The structure of the lasers 10′, 10″ may provide a fast thermal response time of approximately ˜100 microseconds.

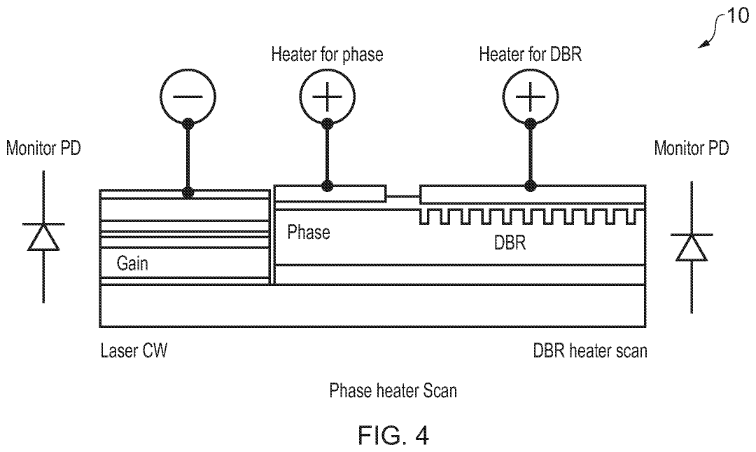

FIG. 4 is a schematic of a laser 10 (such as laser 10′ or 10″) according to an embodiment of the invention. As shown, a first heater is positioned at the phase section, and a second heater is positioned at the DBR section. Power is supplied to the heaters, and the gain section.

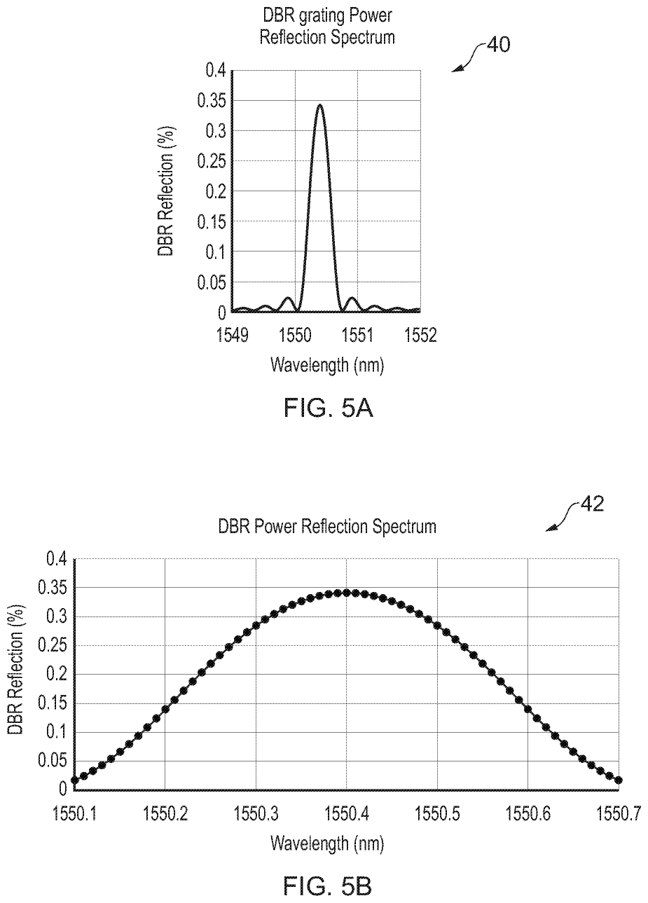

FIG. 5A and FIG. 5B are graphs showing the silicon waveguide DBR grating power reflection spectrum, when the DBR length is 1000 μm, and with a coupling constant, kappa, of 6.688 cm⁻¹.

The external cavity DBR laser longitudinal mode space is given by:

$$Δ {λ}_{m} = \frac{{λ}^{2}}{2 [ {n}_{eg} {L}_{g} + {n}_{ep} {L}_{p} + {n}_{edbr} {L}_{effdbr} ]}$$

where λ is the wavelength of light, L₉ is the gain section length, n_{eg} is the group refractive index of the gain section, Lₚ is the phase section length (including the overlapping region and the thermal isolation region), nₑₚ is the group refractive index of the phase section, L_{effdbr} is the DBR section effective length, and n_{edbr} is the group refractive index of the DBR section. For example, for λ=1550 nm, L_{g}=700 μm, n_{eg}=3.305055 (group index), Lₚ=130 μm, nₑₚ=3.617098 (group index), L_{effdbr}=700 μm, n_{edbr}=3.617098 (group index), then Δλₘ=0.226 nm.

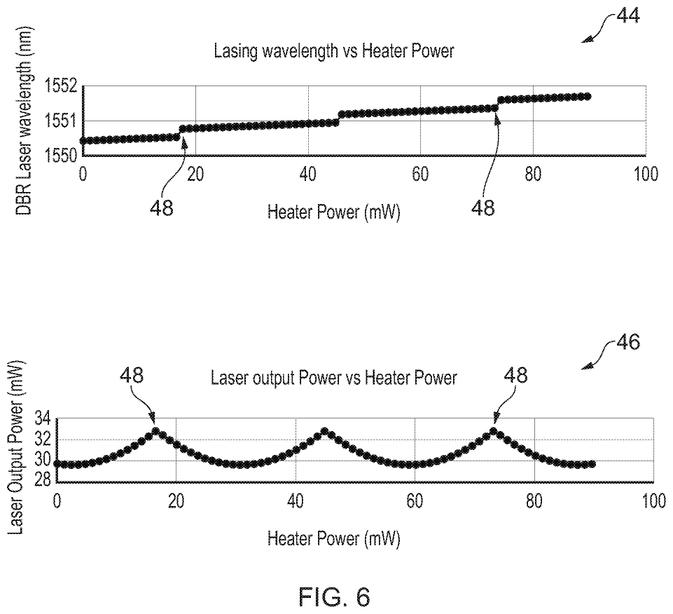

FIG. 6 includes graph 44 showing the effect of increasing the power supplied to a heater on the DBR section 18 of laser 10 in a DBR heater temperature scanning procedure, when the laser gain is biased at the operating current, and a heater at the phase section 16 is biased at a specific power. In particular, as shown in graph 44, when the DBR heater power is increased at a constant power step value, the laser wavelength increases. This increase in wavelength with temperature is not linear; there is a periodic “hopping up” or jump of the wavelength at certain heater power values, i.e. at certain “hopping points” 48. In other words, at the “hopping points”, the difference in wavelength between a pair of adjacent discrete power measurements at the hopping point is greater than the difference in wavelength between pairs of adjacent discrete power measurements away from the hopping point. The difference between the two wavelengths at the hopping point 48 is equivalent to the DBR laser longitudinal mode interval, Δλₘ. As shown in the graph 46 of FIG. 6, the laser output power (e.g. as measured from DBR output facet) reaches a maximum at the hopping points 48.

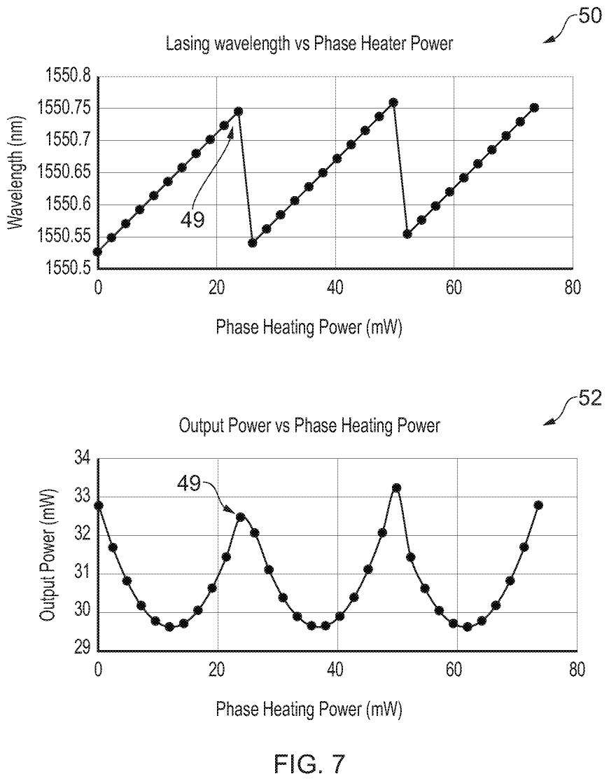

FIG. 7 includes graph 50 showing the effect of increasing the power supplied to a heater on the phase section 16 of laser 10 in a phase heater temperature scanning procedure, when the laser gain is biased at the operating current, and the heater at the DBR section at one of the hopping points 48 described above in relation to FIG. 6. As shown in graph 50, the laser wavelength increases within a mode hopping range (i.e. between adjacent hopping points 49). At each hopping point 49, the laser wavelength drops back to the original wavelength. In this way, with increasing phase heater power, the wavelength periodically changes in a saw tooth-profile. The difference between the two wavelengths at each hopping point 49 is equal to the DBR laser longitudinal mode interval, Δλₘ. As shown in graph 52 of FIG. 7, the laser output power (e.g. as measured from DBR output facet) reaches a maximum value at the hopping points 49. The SMSR is optimized at a position away from the hopping points 49, e.g. at the minimum values of the laser output power, plotted with respect to phase heater power.

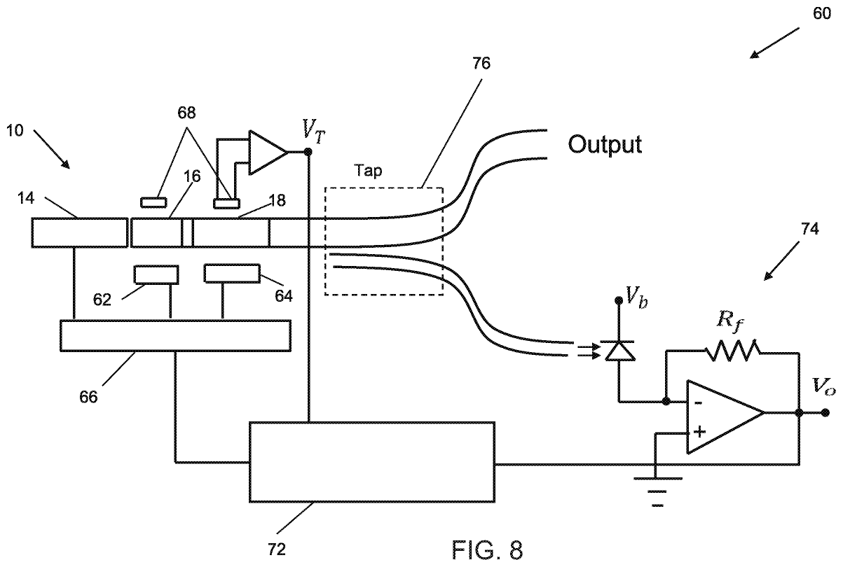

FIG. 8 shows a system 60 for self-characterizing a DBR laser, such as laser 10. A phase heater 62 is positioned at the phase section 16 of the laser, and a DBR heater 64 is positioned at the DBR section 18 of the laser. The phase heater 62, DBR heater 64 and gain section 14 are powered by one or more power sources (ADC) 66. Temperature sensors 68 are positioned near or adjacent to the phase section 16 and DBR section 18 to detect the temperature of the phase section and DBR section. The system 60 also comprises a controller 72 (e.g. a microcontroller unit, MCU) and a monitor photodiode detector (MPD) 74. An optical splitter 76 splits the output from laser 10 such that some (e.g. 3%) of the power is directed to the MPD.

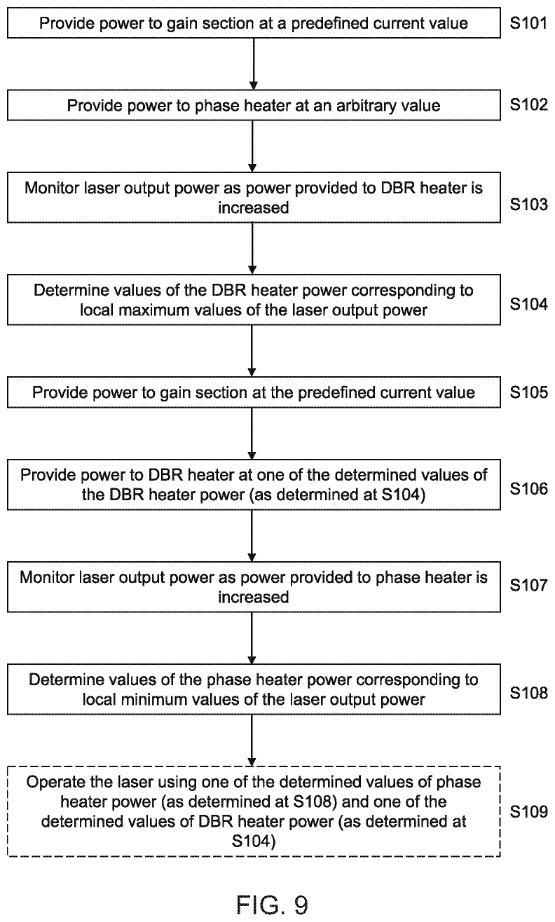

The controller 72 is connected to the temperature sensors 68, the MPD and the one or more power sources 66, in order to implement self-characterization of laser 10. In particular, the controller 72 acquires the DBR laser output power data (e.g. using MPD 74 and/or temperature sensors 68) during a DBR and phase thermal tuning process (also referred to as DBR and phase heater temperature scanning processes, respectively), finds the mode hopping points of the laser output power and the corresponding DBR heater 64 and phase heater 62 power values, and sets the DBR heater 64 and phase heater 62 power values based on the mode hopping points of the laser output power and the corresponding DBR heater 64 and phase heater 62 power values. System 60 can therefore find preferred, or optimal, operating points for the gain section 14, the phase section 16, and the DBR section 18. This DBR laser self-characterization method is described in further detail below with respect to FIG. 9.

FIG. 9 is a flowchart of a laser self-characterization method. First, a DBR heater temperature scanning procedure (S101-S104) is performed. In particular, at S101, power is provided to the gain section 14 (e.g. by power source 66) at an operating current (which may be predefined, e.g. by application specification). At S102, power is provided to the phase heater 62 at an arbitrary power value (which may be zero, or a low power compared to the power provided to the gain section, for example). At S103, the power provided to the DBR heater 64 is increased (e.g. at a constant, discrete step value). As the power provided to the DBR heater 64 is increased in this step wise manner, the output power of the laser 10 is monitored, e.g. using MPD 74. A plurality of measurements (e.g. 10-20) of the output power of the laser may be sampled for each DBR heater power value in order to remove noise. The laser wavelength may also be monitored using techniques known in the art. As described above in relation to FIG. 6, with increasing DBR heater power, the laser output power cyclically reaches a maximum value at the hopping points 48, with the laser output power falling between these hopping points 48. This is an intrinsic characteristic of the laser. Thus, at S104, in order to maximize performance (e.g. output power) of the laser, the values of DBR heater power corresponding to the maximum value of laser output power are determined and recorded. These recorded DBR heater values are preferred, or optimal, power values for the DBR heater 64, corresponding to laser output power local extreme points. Any of these recorded DBR heater values may be applied to the DBR heater 54 to maximize laser output performance. These local extremes of the laser output power are selected for laser self-characterization as they are computationally simpler to find compared to other approaches.

Next, after the DBR heater temperature scanning procedure, a phase heater temperature scanning procedure (S105-S109) is performed. At S105, power is provided to the gain section 14 at the operating current (e.g. the power provided may be maintained between the DBR heater temperature scanning procedure and the phase heater temperature scanning procedure, or may be paused then reapplied). At S106, power is provided to the DBR heater 64 at one of the recorded DBR heater values (i.e. one of the DBR heater values for which the laser output power is maximized). At S107, the power provided to the phase heater 62 is increased (at a constant, discrete step value). As the power provided to the phase heater 62 is increased in this step wise manner, the output power of the laser 10 is monitored, e.g., using MPD 74. A plurality of measurements (e.g. 10-20) of the output power of the laser may be sampled for each phase heater power value in order to remove noise. The laser wavelength may also be monitored. As described above in relation to FIG. 7, with increasing phase heater power, the laser output cyclically reaches a maximum value at the hopping point 49, with the laser output power falling between these hopping points 49. The SMSR is optimized at a position away from the hopping points 49, e.g. at the minimum values of the laser output power, plotted with respect to phase heater power. Thus, at S.108, in order to maximise the SMSR of the laser, the values of the phase heater power corresponding to the minimum values of laser output power are recorded. In practice, a phase heater power value corresponding to a minimum value of laser output power may be calculated by dividing the sum of the phase heater power values corresponding to two adjacent maximum values of laser output power, by 2. The recorded phase heater power values are preferred, or optimal, power values for the phase heater 62 in order to maximize the SMSR ratio of the laser. Any of the recorded phase heater values may be applied to the phase heater 62 to maximize the SMSR of the laser. Preferably, the lowest power value of the recorded phase heater values may be chosen.

Therefore, this self-characterization method allows for optimized DBR heater and phase heater bias point values to be determined, without human intervention. This reduces the time and labour costs required, e.g. compared to manual testing.

Optionally, the method may further comprise, at S109, operating the laser by providing power at the operating current to the gain section, providing power to the phase heater 62 at one of the determined optimized phase heater values, and providing power to the DBR heater 64 at one of the determined DBR heater values.

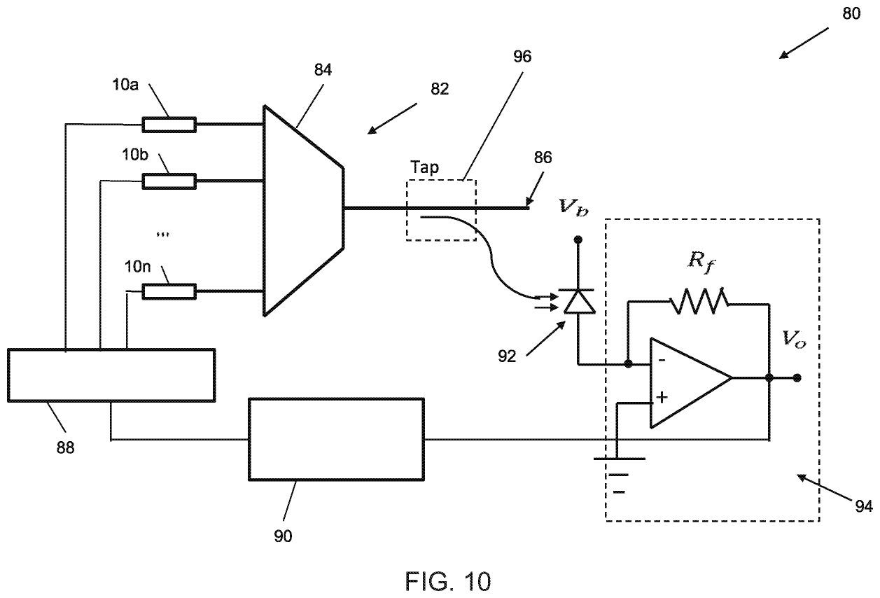

FIG. 10 is a schematic of a system 80 for self-characterizing a spectrometer 82. Spectrometer 82 comprises a plurality of lasers 10a, 10b . . . 10n (e.g. laser 10 described above). Each of the lasers 10a, 10b, 10n, and in particular each of the outputs of the lasers, are optically coupled to an optical manipulation region comprising an optical wavelength multiplexer, MUX, 84. The output of the MUX 84 is coupled to an optical outlet 86, such as an optical port. Power is independently supplied to each of the lasers 10a, 10b, 10n, and in particular each photonic component, DBR heater, and phase heater of each laser, via one or more power sources, ADC, 88. The power supply to the lasers 10a, 10b, 10n is controlled by a controller (e.g. microcontroller unit 90). The system 80 also comprises a monitor photodiode detector (MPD) 92 and a transimpedance amplifier, TIA, 94. An optical splitter 96 splits the output from MUX 84 such that some (e.g. 3%) of the power is directed to the MPD 92, instead of to optical outlet 86. The controller 90 is connected to the TIA 94 and is configured to self-characterize the spectrometer 82, so that the maximum output power is output from the optical outlet (and align the wavelength of light output from the lasers to that output from the MUX). In addition, or as an alternative, to the optical splitter 96, some or all of the light output from the MUX 84 may be reflected to a receiver, which can align the DBR laser source wavelength with the MUX pass band peak, as set out below.

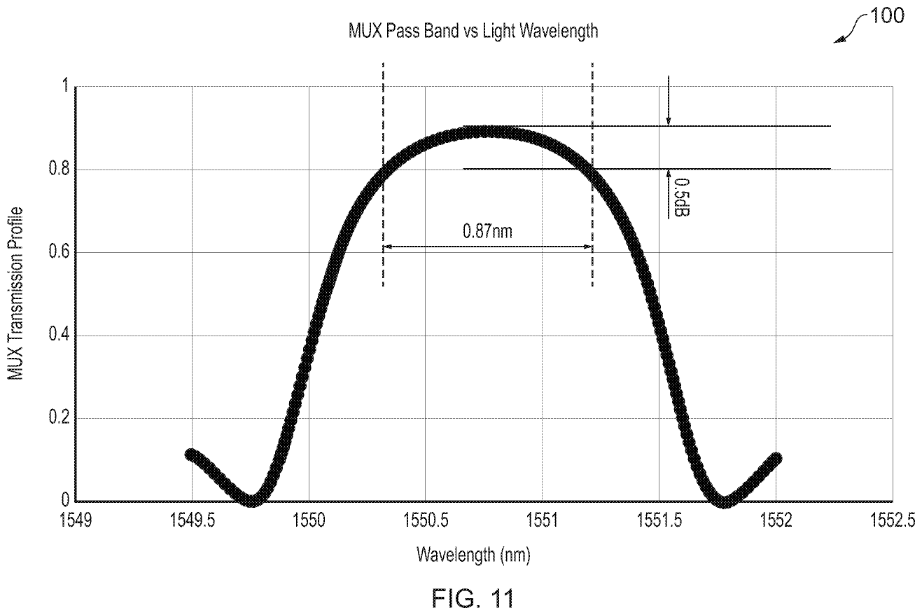

Graph 100 of FIG. 11 is an optical wavelength multiplexer channel pass band profile, e.g. an example MUX transmission profile is plotted against wavelength of output light. As shown in graph 100, for a bandwidth of 0.87 nm, there is a channel loss variation of 0.5 dB. The MUX output power spectrum is a function of DBR heater power, Hᵢ, (e.g. the power supplied to each DBR heater in each of lasers 10a, 10b, . . . 10n). In particular, the MUX output power spectrum (P_{RPS}) is defined as:

P_{RPS}(Hᵢ)=P_{DBR}(Hᵢ)·MUX_{PB}(λᵢ)

where λᵢ=f(Hᵢ), P_{DBR}(Hᵢ) is the DBR laser output power spectrum, MUX_{PB}(λᵢ) is the optical wavelength multiplexer each channel pass band spectrum, and i is the DBR heater power increasing step number.

Returning to FIG. 10, system 80 is configured to tune the wavelength of light output from the optical outlet 86 of the spectrometer 82, e.g. to align the DBR laser source wavelength with the MUX pass band peak.

In order to do this, the wavelength of light with the minimum loss has to be found. As mentioned above in relation to S104, for each laser, a plurality of DBR heater power values may be recorded and they may each be preferred, or optimal, power values for the DBR heater in order to maximize the performance of that laser and characterize that laser automatically. However, some of these DBR heater power values may shift the wavelength of light output from that laser such that it is not aligned with the MUX pass band peak (thus resulting in less power being output from MUX 84).

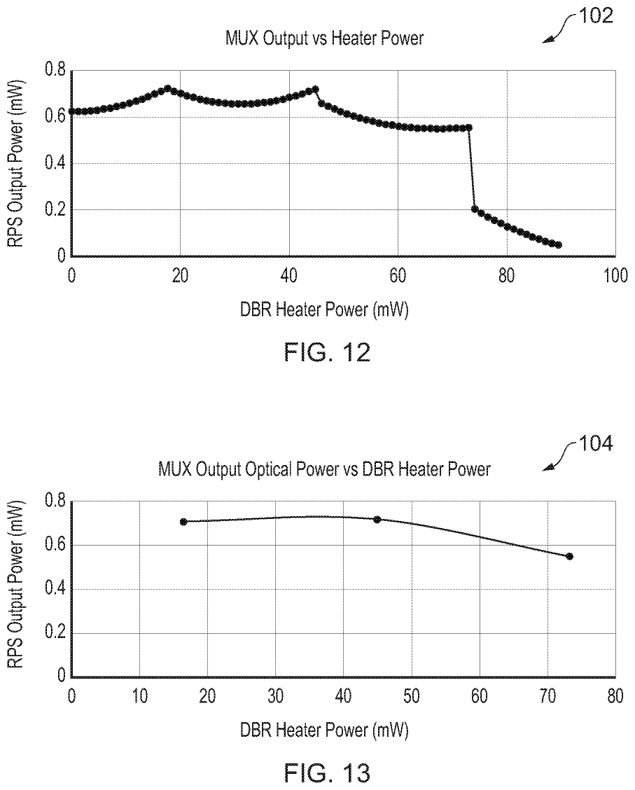

Therefore, in order to select the optimal DBR heater power value for each laser when coupled to the MUX 84 in spectrometer 82, the DBR heater scanning procedure must be repeated for each laser 10a, 10b, 10n. Therefore, for each laser 10a, 10b, 10n in turn, the following DBR heater scanning procedure is performed. First, power is provided to the photonic component (e.g. the Reflection Semiconductor Optical Amplifier, RSOA) of a first laser 10a at the operating current (which may be predefined, e.g. by application specification), in turn. The power supplied to the phase heater of the first laser 10a is set to 0. Next, the power provided to the DBR heater 64 of the first laser 10a is increased (e.g. at a constant, discrete step value). The values of the power provided to the DBR heater 64 in this step-wise process may be the plurality of recorded DBR heater values which were found in the DBR heater scanning process described above in relation to S104 of FIG. 9, or they may be arbitrarily chosen power values (e.g. a constant discrete step value). As the power provided to the DBR heater 64 of laser 10a is increased, the output power of the MUX 84 is monitored, e.g. using MPD 74 and/or TIA 94. A plurality of measurements (e.g. 10-20) of the output power of the MUX 84 may be sampled for each DBR heater power value in order to remove noise. The output wavelength may also be monitored. An example graph 102 of MUX output power plotted against DBR heater power for a laser in a spectrometer (such as spectrometer 82) is shown in FIG. 12.

In order to maximize output power of the MUX, the value of DBR heater power corresponding to the maximum value of MUX output power is determined and recorded. This recorded DBR heater value is a preferred, or optimal, power value for the DBR heater 64 of laser 10a, in order to maximize MUX output power of the spectrometer 82.

Optionally, in order to reduce power consumption of the tuning process, only the plurality of recorded DBR heater values which were found in the DBR heater scanning process described above in relation to S104 of FIG. 9 are used as the values of the power provided to the DBR heater. As such, only the DBR heater power preferred values which are related to local extreme laser output power are selected. In this way, less DBR heater power values are used to perform the DBR heater power scanning procedures. For example, if three DBR heater power values have been selected during the DBR heater power scanning procedure, only three laser output values from the MUX outlet port will be recorded. Example results are shown plot 104 of FIG. 13 (with the three DBR heater power values corresponding to the three maximum “hopping points” 48 in FIG. 6). The DBR heater power value that corresponds to the maximum optical output power is selected as the preferred DBR heater power value. This is an alternative approach to align DBR laser wavelength with MUX passband peak wavelength which uses less processing power than scanning arbitrarily chosen DBR heater power values.

The DBR heater scanning process is then repeated for each of the other lasers 10b, 10n in turn. The recorded phase heater value as determined and recorded in S108 of the method of FIG. 9 may be used as the optimal phase heater power value for each respective phase heater of the lasers 10a, 10b, 10n. The pairs of optimal DBR heater power value and phase heater power value determined as set out above may then be recorded and used as the best operating points for the respective laser, in spectrometer 82.

While the invention has been described in conjunction with the exemplary embodiments described above, many equivalent modifications and variations will be apparent to those skilled in the art when given this disclosure. Accordingly, the exemplary embodiments of the invention set forth above are considered to be illustrative and not limiting. Various changes to the described embodiments may be made without departing from the spirit and scope of the invention. All references referred to above are hereby incorporated by reference.

For the avoidance of any doubt, any theoretical explanations provided herein are provided for the purposes of improving the understanding of a reader. The inventors do not wish to be bound by any of these theoretical explanations.

Throughout this specification, including the claims which follow, unless the context requires otherwise, the word “comprise” and “include”, and variations such as “comprises”, “comprising”, and “including” will be understood to imply the inclusion of a stated integer or step or group of integers or steps but not the exclusion of any other integer or step or group of integers or steps.

It must be noted that, as used in the specification and the appended claims, the singular forms “a,” “an,” and “the” include plural referents unless the context clearly dictates otherwise. Ranges may be expressed herein as from “about” one particular value, and/or to “about” another particular value. When such a range is expressed, another embodiment includes from the one particular value and/or to the other particular value. Similarly, when values are expressed as approximations, by the use of the antecedent “about,” it will be understood that the particular value forms another embodiment. The term “about” in relation to a numerical value is optional and means for example +/−10%.

What is claimed is:

1. A laser comprising:
a photonic component comprising a gain medium; and
a waveguide platform comprising a Distributed Bragg Reflector, DBR, section, wherein the photonic component is optically coupled to the waveguide platform, and wherein one or more thermal heaters are positioned at the DBR section of the waveguide platform, and/or at a phase section of the waveguide platform located between the gain medium and the DBR section.

2. The laser of claim 1, wherein the waveguide platform is a silicon on insulator, SOI or a silicon nitride platform.

3. The laser of claim 1 or claim 2, wherein the photonic component comprises a Reflection Semiconductor Optical Amplifier, RSOA or a III-V compound semiconductor gain chip.

4. The laser of any preceding claim wherein the DBR section comprises an optical mirror configured to selectively reflect light having a wavelength within a predetermined range of wavelengths.

5. The laser of any preceding claim, wherein the photonic component is a III-V semiconductor.

6. The laser of any preceding claim, wherein the phase section of the waveguide platform is thermally isolated from the DBR section.

7. The laser of any preceding claim, wherein the phase section of the waveguide platform is thermally isolated from the DBR section of the waveguide platform by a thermal isolation space between the phase section and the DBR section.

8. The laser of any preceding claim, wherein the one or more heaters comprise metal or heavy doped silicon.

9. The laser of any preceding claim, wherein a first heater is positioned on the phase section of the waveguide platform and a second heater is positioned on the DBR section of the waveguide platform.

10. The laser of any preceding claim, wherein the one or more heaters and the photonic component are configured to receive power from one or more power sources.

11. The laser of any preceding claim, wherein the one or more heaters are positioned on a ridge of the waveguide platform.

12. The laser of any preceding claim, wherein the one or more heaters are positioned adjacent to a ridge of the waveguide platform, and extend in a longitudinal direction parallel to the ridge of the waveguide platform.

13. The laser of any preceding claim, comprising a SiO₂ layer between the one or more heaters and the waveguide platform.

14. A method of characterizing a laser according to any preceding claim, wherein the laser comprises a DBR heater positioned at the DBR section, the method comprising:
determining an optimal DBR heater power value to be supplied to the DBR heater, wherein determining the optimal DBR heater power value comprises:
providing power to the photonic component;
providing power to the phase heater;
monitoring the output power of the laser as power provided to the DBR heater is increased; and
selecting the optimal DBR heater power value based on the monitored output power of the laser.

15. The method of claim 14, wherein the selected optimal DBR heater power value corresponds to a local maximum of the monitored output power of the laser as the power supplied to the DBR heater is increased.

16. The method of claim 14 or claim 15, wherein the laser comprises a phase heater positioned at the phase section, the method comprising:
determining an optimal phase heater power value to be supplied to the phase heater, wherein determining the optimal phase heater power comprises:
providing power to the photonic component;
providing power to the DBR value at the selected optimal DBR heater power value;
monitoring the output power of the laser as power provided to the phase heater is increased; and
selecting the optimal phase heater power value based on the monitored output power value of the laser.

17. The method of claim 16, wherein the selected optimal phase heater power value corresponds to a local minimum of the monitored output power of the laser as the power supplied to the phase heater is increased.

18. The method of claim 16 or claim 17, further comprising operating the laser using the determined optimal DBR heater power value and the determined optimal phase heater power value.

19. A spectrometer comprising:
a plurality of lasers according to any of claims 1-13;
an optical manipulation region comprising an optical multiplexer, the optical manipulation region being optically coupled to each of the plurality of devices; and
an optical output for light originating from the plurality of lasers.

20. A method of characterizing a spectrometer according to claim 19, wherein each laser in the spectrometer comprises a DBR heater positioned at the DBR section, the method comprising:
determining an optimal DBR heater power value to be supplied to the DBR heater of a first laser of the plurality of lasers, wherein determining the optimal DBR heater power value for the first laser comprises:
(i) providing power to the photonic component of the first laser;
(ii) monitoring the output power of the optical multiplexer as power provided to the DBR heater of the first laser is increased;
(iii) selecting the optimal DBR heater power value of the first laser, wherein the selected optimal DBR heater power value corresponds to a maximum output power of the optical multiplexer as the power supplied to the DBR heater of the first laser is increased; and
determining an optimal DBR heater power value to be supplied to the DBR heater of each of the remaining lasers of the plurality of lasers by performing steps (i)-(iii) for each of the remaining lasers in turn.

21. The method of claim 20 wherein characterizing the spectrometer includes aligning the output wavelength of each laser source with the optical multiplexer pass band peak.
